(19) United States
(12) Patent Application Publication
(10) Pub. No.: US 2006/0091537 A1
(43) Pub. Date: May 4, 2006

(54) Semiconductor device and method of fabricating the same

(75) Inventor: Seiichi Suzuki, Aizuwakamatsu-shi (JP)

Correspondence Address: INGRASSIA FISHER & LORENZ, P.C., 7150 E. CAMELBACK, STE. 325, SCOTTSDALE, AZ, 85251, US

(73) Assignee: SPANSION LLC

(21) Appl. No.: 11/257,825

(22) Filed: Oct. 24, 2005

Related U.S. Application Data
(63) Continuation of application No. PCT/JP04/16120, filed on Oct. 29, 2004.

(51) Int. Cl. H01L 23/48; H01L 23/52

(52) U.S. Cl. 257/734; 257/738

(57) ABSTRACT

Slit-like gap regions are provided at sides of a bonding pad that surrounds a window for bonding. The bonding pad is divided into a region at the side of the window and another region at the side of an adjoining interconnection layer in which the gap regions are the boundaries between these regions. The region provided at the side of the wiring layer is spaced apart from the region at the side of the bonding window by the width of the associated gap region. The gap regions are filled with a passivation film that is soft as compared with Top-side. Thermal stress is absorbed and distributed by the gap regions, and diffusion of metal atoms from the region at the side of the window to the region at the side of the interconnection layer is reduced.

### CROSS-REFERENCES TO RELATED APPLICATIONS

This is a continuation of International Application No. PCT/JP2004/016120, filed Oct. 29, 2004 which was not published in English under PCT Article 21(2).

### TECHNICAL FIELD

The present invention relates to semiconductor devices, and more particularly, to the technique for preventing electrical short-circuiting between a bonding pad of the semiconductor device and an interconnection line.

### BACKGROUND OF THE INVENTION

Semiconductor devices wherein a connection pad (bonding pad) and an electrode provided on a semiconductor substrate are connected by an interconnection line are known. However, thermal stresses may occur due to the difference in the coefficients of thermal expansion between the interconnection line and a protection film. These stresses may cause the interconnection line and/or the protection film to crack.

Japanese Patent Application No. 2004-22653 discloses one solution to the above problem. Accordingly, a slit is provided in the rerouting pattern that surrounds a connection pad and a bump electrode. The slit functions to distribute and dissipate stress caused when a bump electrode is pressure contacted to the pad or bump electrode, so that the occurrences of short-circuiting and disconnection failures can be minimized.

However, modern semiconductor devices have miniaturized layout elements in the vicinity of the bonding pads due to advanced design rules. For example, it is necessary to downsize the bonding pads, the width of the overlap region between the bonding pad and the passivation film, and the pitch between the adjacent metal interconnection lines. This downsizing may cause cracks and short-circuits due to diffusion of metal atoms (for example, gold atoms and aluminum atoms) of the material used to make the interconnection. Such cracks would typically not be caused when conventional design rules were employed.

More particularly, a crack may occur in the passivation film due to thermal expansion of an aluminum interconnection layer due to diffusion of gold atoms of a gold bonding wire into the aluminum interconnection layer. This may be due to the thermal resin molding process after metallization during the assembly process and other thermal stresses during the use of the semiconductor device. It is also possible that atoms of the interconnection metal may intrude into the crack and electrically short to the adjacent interconnection layer.

FIGS. 1(a) through 1(c) illustrate a technique for solving the above problems. More particularly, FIG. 1(a) is a schematic plan view of a positional relationship between a bonding pad 11 and an adjacent interconnection layer 12, and FIGS. 1(b) and 1(c) are respectively cross-sectional views taken along a line C-C′ shown in FIG. 1(a). FIG. 1 (b) shows the state before a bonding wire 16 is bonded to bonding pad 11, and FIG. 1(c) shows the state after the bonding. The device includes a passivation film 13 for surface protection, an insulating film 14 formed on a semiconductor substrate 15, and an opening window 18 for bonding provided in the bonding pad 11. Reference numeral 17 indicates a crack that occurs in the passivation film 13.

Bonding pad 11 and interconnection layer 12 are formed, using standard photolithography techniques, on insulating film 14 which is in turn grown on p-type semiconductor substrate 15 by chemical vapor deposition (CVD). Next, passivation film 13 is deposited to cover a portion of the bonding pad 11 and the interconnection layer 12. It may be assumed that both bonding pad 11 and interconnection layer 12 are made of aluminum, and the bonding wire 16 connected to the bonding window 18 in bonding pad 11 is gold. The bonding wire 16 is used to electrically connect bonding pad 11 to a leadframe provided outside of the chip (not shown).

After bonding wire 16, the chip is sealed with mold resin. The gold atoms of the bonding wire 16 diffuse and intrude into the aluminum bonding pad 11 in the bonding region (connecting region) between the bonding wire 16 and the bonding pad 11 due to heat applied during the sealing process and the environmental temperature of the semiconductor device when in use. The gold atoms that enter the aluminum bonding pad 11 quickly diffuse therein causing a cubical expansion depending on the concentration thereof.

If the expansion progresses and the difference in thickness between the bonding pad 11 and the interconnection layer 12 exceeds a given threshold, a crack 17 occurs in the passivation film 13, as shown in FIG. 1(c). The gold and aluminum atoms, which cause the cubical expansion, intrude into the crack 17 from the bonding pad 11. If these atoms reach interconnection layer 12, bonding pad 11 and the interconnection layer 12 are electrically short-circuited. In addition, moisture in the ambient atmosphere intrudes through crack 17 and causes corrosion of the interconnection layer 12.

The degree of intrusion of the metal atoms into the crack (the amount of intrusion and the length thereof) depends on the temperature and time applied. In order to prevent a device failure due to the diffusion of metal atoms, the connecting position of the bonding wire 16 to the bonding pad 11 may be arranged with a margin such that the connecting position is separated from the edge of the bonding pad 11 (for example, L1 shown in FIG. 1(c) is at least 8 μm), or the space between the bonding pad 11 and the interconnection layer 12 is designed to exceed a given value (for example, L2 is at least 15 μm). However, solutions of this type increase chip size.

### SUMMARY OF THE INVENTION

A semiconductor device and a method of fabricating same is provided that is suitable for advanced design rules and prevents short-circuiting between a bonding pad and an interconnection layer.

The semiconductor device comprises: a bonding pad; and an interconnection line close to the bonding pad, wherein the bonding pad has a gap region that is provided in a region proximate to the interconnection line and runs in a direction substantially identical to a direction in which an edge of the bonding pad facing the interconnection line extends.

The semiconductor device may be configured so that the bonding pad has at least three gap regions that are provided in the region proximate to the interconnection line and are arranged into lines. The semiconductor device may further comprise a single protection film that covers the interconnection line and a part of the bonding pad, wherein the gap region located in the part of the bonding part is filled with a part of the protection film. In this case, it is possible to employ a structure in which: the bonding pad has a window provided in an inner region thereof and used to bond a wire; and any of the at least three gap regions is provided in the window.

The protection film may be a multilayer film having a first relatively soft insulating film and a second relatively insulating hard film, and the part of the protection film provided in the gap region may include a part of the first insulating film. The first insulating film may be an SOG film, and the second insulating film may be a silicon nitride film. The semiconductor device may further include sidewalls provided on sidewalls of the bonding pads that surround the gap region. The sidewalls may be made of titanium or an alloy containing titanium. The semiconductor device may further include a silicon oxide film that covers a buried interconnection pattern, wherein the bonding pad and the interconnection line are provided on the silicon oxide film.

The present invention includes a method of fabricating a semiconductor device comprising: providing a conductive layer on an insulating layer; and patterning the conductive layer into a bonding pad and an interconnection line close to the bonding pad so that that the bonding pad has a gap region that is provided in a region proximate to the interconnection line and runs in a direction substantially identical to a direction in which an edge of the bonding pad facing the interconnection line extends. The method may further include forming a window provided in an inner region of the bonding pad and used to bond a wire.

The present invention includes a method of fabricating a semiconductor device comprising: forming a buried interconnection pattern covered by an insulating layer; providing a conductive layer on the insulating layer; and patterning the conductive layer into a bonding pad and an interconnection line close to the bonding pad so that that the bonding pad has a gap region that is provided in a region proximate to the interconnection line and runs in a direction substantially identical to a direction in which an edge of the bonding pad facing the interconnection line extends.

### BRIEF DESCRIPTION OF THE DRAWINGS

The present invention will hereinafter be described in conjunction with the following drawing figures, wherein like numerals denote like elements, and

FIGS. 1(a), 1(b) and 1(c) illustrate problems associated with the prior art, wherein FIG. 1(a) is a schematic plan view of the positional relationship between a bonding pad and an adjacent interconnection layer, and FIGS. 1(b) and 1(c) are respectively cross-sectional views taken along a line C-C′ in FIG. 1(a), wherein FIG. 1(b) shows the state before a bonding wire is bonded to the bonding pad, and FIG. 1(c) shows the state after the bonding;

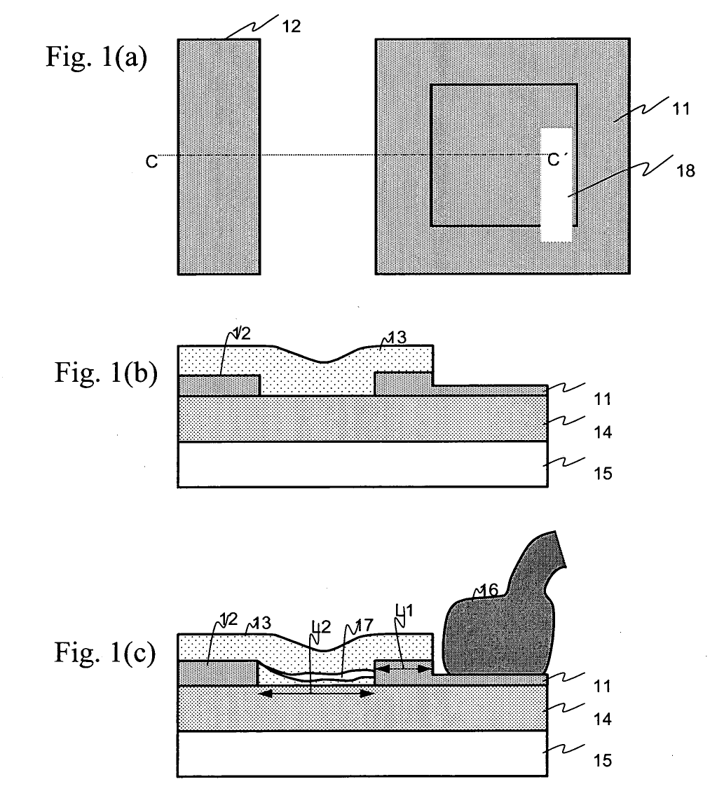

FIGS. 2(a), 2(b) and 2(c) illustrate a layout of a semiconductor device having a bonding pad and an adjoining interconnection layer according to the present invention, wherein FIG. 2(a) is a schematic plan view of the positional relationship between the bonding pad and the interconnection layer proximate to each other, and FIGS. 2(b) and 2(c) are respectively cross-sectional views taken along a line A-A′ shown in FIG. 2(a);

FIGS. 3(a) and 3(b) are cross sectional views of a semiconductor device observed after an acceleration test, wherein FIG. 3(a) shows a semiconductor device having the invention layout, and FIG. 3(b) shows a semiconductor device having the conventional layout;

FIG. 4 is a plan view illustrating an arrangement in which a gap region is provided in a window for bonding; and

FIGS. 5(a) and 5(b) illustrate another layout of a bonding pad and an adjoining interconnection layer of a semiconductor device according to the present invention, wherein FIG. 2(a) is a schematic plan view of the positional relationship between the bonding pad and the interconnection layer proximate to each other, and 5(b) is a cross-sectional view taken along a line B-B′ shown in FIG. 5(a).

### DETAILED DESCRIPTION OF THE INVENTION

The following detailed description of the invention is merely exemplary in nature and is not intended to limit the invention or the application and uses of the invention. Furthermore, there is no intention to be bound by any theory presented in the preceding background of the invention or the following detailed description of the invention.

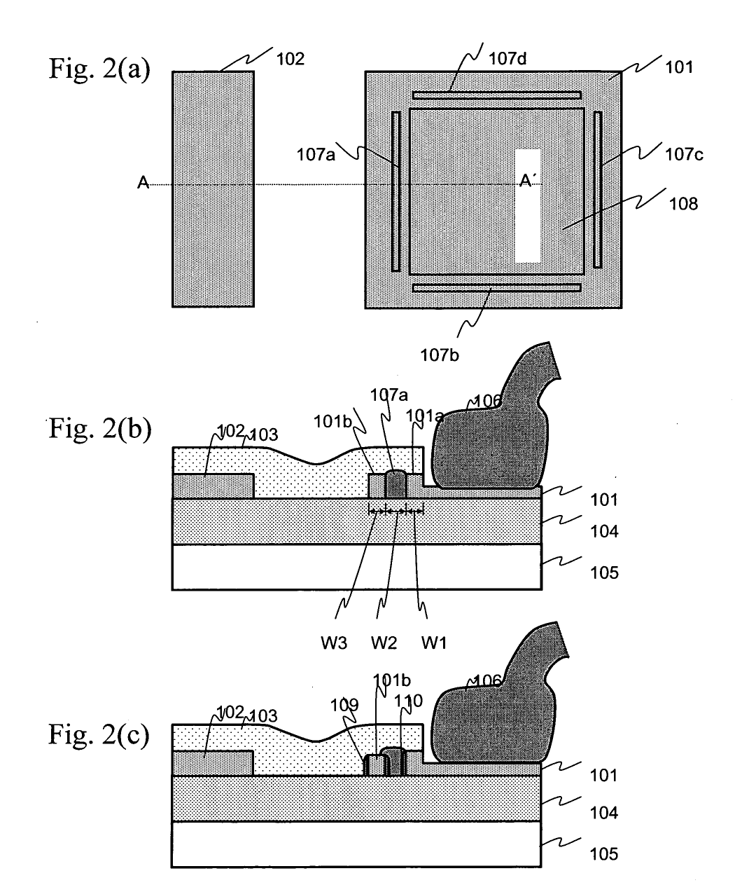

FIGS. 2(a) through 2(c) show an exemplary layout of a bonding pad of a semiconductor device and an interconnection layer proximate to the bonding pad in accordance with a first embodiment of the invention. More particularly, FIG. 2(a) is a schematic plan view showing the positional relationship between a bonding pad 101 and an interconnection layer 102 that are arranged close to each other, and FIG. 2(b) is a cross-sectional view taken along a line A-A′ shown in FIG. 2(a). There is shown a passivation film 103 for surface protection, an insulating film 104 formed on a semiconductor substrate 105, and an opening window 108 for bonding provided in bonding pad 101. A bonding wire 106 is connected to window 108 for bonding.

The semiconductor device has a slit-like gap region 107 a-d each running along a side of the bonding pad 101 that is involved in defining the window 108. The illustrated example assumes that interconnection layers (not shown) are provided on the upper, lower and right sides of the bonding pad 101. Thus, gap regions 107 a-d are provided each along one of the four sides of bonding pad 101. However, in practice, it is sufficient to provide a gap region only along the side of the bonding pad on which the interconnection layer is actually arranged. Thus, if interconnection line 102 is arranged close to the bonding pad 101, only gap region 107a is provided.

FIG. 2(b) is a cross sectional view taken along the line A-A′ in FIG. 2(a), of bonding pad 101 in which the gap region 107a is formed. As shown, bonding pad 101 is divided into a region 101a at the side of the window 108 and a region 101b nearer to the side of the adjoining interconnection layer 102, gap region 107a forming a boundary between regions 101a and 101b. Region 101b provided at the side of wiring layer 102 is spaced apart from region 101a by the width of the gap region 107a. In addition, gap region 107a is filled with a part of the passivation film 103. Thus, gap region 107a functions to shut out heat applied during the sealing process (for example, 200° C., 5 hours) after the sealing bonding wire 106 is connected and metal molecules of the bonding wire 106 are diffused into region 101b due to the ambient temperature in which the semiconductor device is used. That is, the diffusion does not occur virtually. The crack resulting from cubical expansion may occur in gap region 107a. However, the occurrence of the crack reduces the cubical expansion and prevents a crack from occurring in the interconnection layer 102.

The above-described layout can be realized using the following miniaturization process. Insulating film 104 is formed by growing a silicon oxide film (which is approximately 800 nm thick) on the main surface of the p-type semiconductor substrate 105 having a resistivity of 20 Ω·m. Next, bonding pad 101 and interconnection layer 102 are formed on the insulating film 104 using standard photolithography techniques. Bonding pad 101 and interconnection layer 102 may be formed by growing an AlCu alloy (Cu: 0.5 wt %) to a thickness of approximately 500 nm using PVD and patterning the AlCu alloy film into the respective shapes. During the process of patterning, the metal of the bonding pad 101 is partially removed in specific positions (for example, all of the four sides surrounding window 108 for bonding) so that the gap regions 107a-d are formed.

Subsequently, a silicon nitride film is grown to a thickness of approximately 1000 nm by CVD, and is coated with passivation film 103 at specific locations. Then, the film is partially removed by etching so that bonding window 108 is formed in the inner area of bonding pad 101. Next, bonding wire 106 is bonded to the inner region of the bonding pad 101 exposed through the window 108. The bonding wire 106 may be a gold wire having a diameter of, for example, 30 nm.

In the exemplary structure shown in FIGS. 2A through 2C, each side of the window 108 is approximately 90 μm thick. Region 101a at the side of the window 108 in the bonding pad 101 has a width W1 of approximately 2 μm, and gap region 107a has a width W2 of approximately 1 μm. Region 101b at the side of interconnection line 102 has a width W3 of approximately 2 μm.

As shown in FIG. 2(c), sidewalls 109 and 110 containing Ti or an alloy of Ti may be provided on the sidewall of region 101a closer to window 108 for bonding the bonding pad 101 and the sidewalls of regions 101b closer to the interconnection layer 102, as necessary.

An acceleration test (150° C., 1000 hours) was carried out for the semiconductor device having the layout of the present invention, and the results of the test were compared with those of a semiconductor device having a conventional layout in order to investigate the reliability of the semiconductor device of the invention.

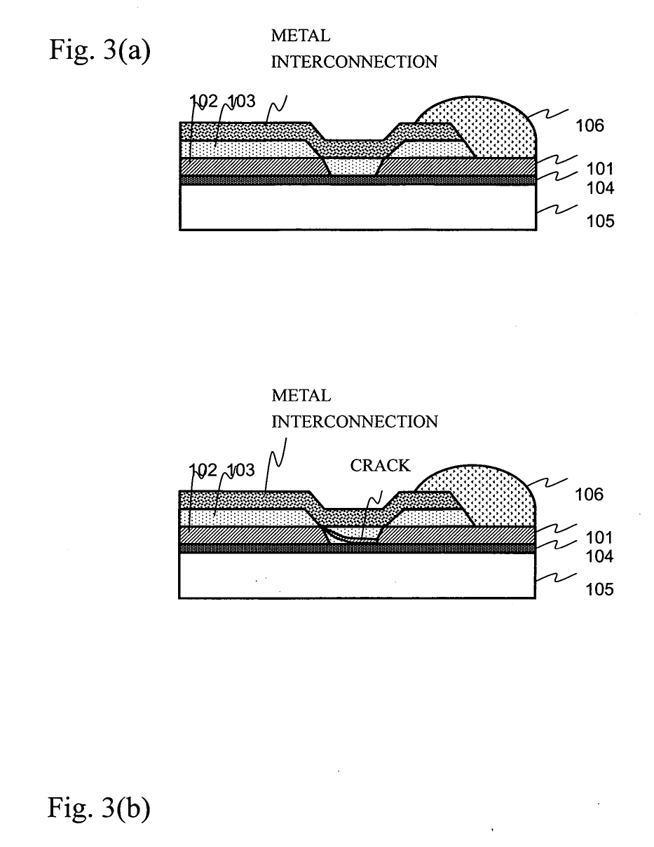

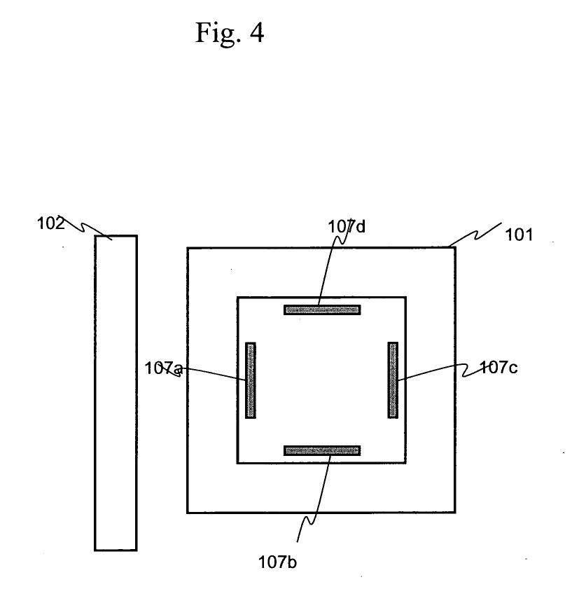

FIGS. 3(a) and 3(b) are cross sectional views of semiconductor devices after the above-described acceleration test (FIG. 3(a) shows a semiconductor device having the inventive layout, and FIG. 3(b) shows a semiconductor device having a conventional layout). In the conventional semiconductor device, a crack is caused by applied heat, and metal that intrudes from the bonding pad reaches to the adjoining interconnection layer and causes short-circuiting. In contrast, referring to FIG. 3a, the gap regions 107a-d absorb and distribute stress, and the junction of different metals in the region 101b of the bonding pad 101 closer to the interconnection layer 102 physically restrains the movement of metal. As a result, the junction functions as a barrier for diffusion of metal atoms, and no cracks extending to the interconnection layer 102 are observed. The gap regions may be provided within the window 108 in the bonding pad 101 as shown in FIG. 4. The gap regions 107a through 107d are respectively approximately 1 μm wide and approximately 20 μm long.

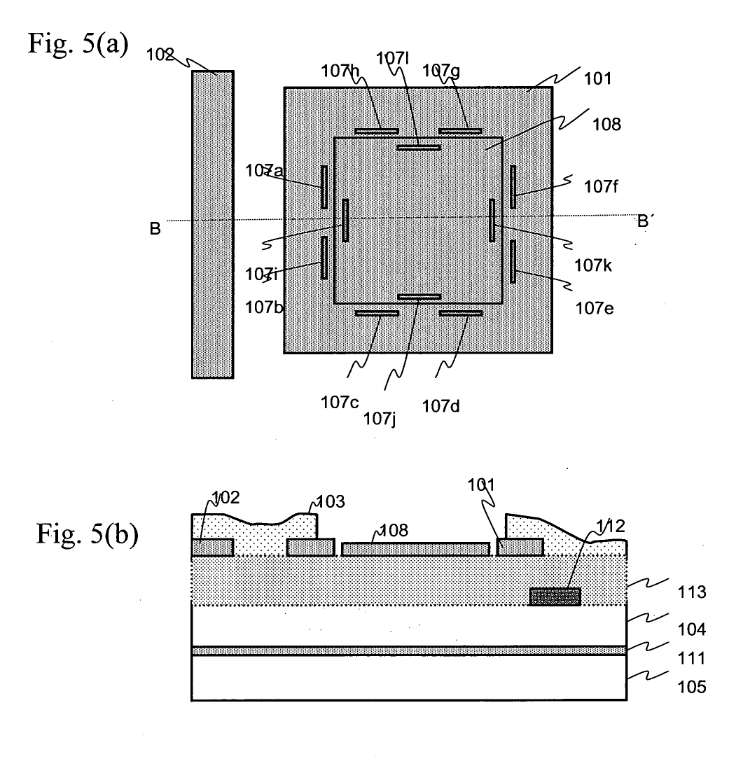

FIGS. 5(a) and 5(b) are top and cross-sectional views respectfully of a layout having a bonding pad and an interconnection layer proximate to the bonding pad in accordance with a second embodiment of the present invention. More particularly, FIG. 5(a) is a schematic plan view showing the spatial relationship between bonding pad 101 and interconnection layer 102, and FIG. 5(b) is a schematic cross-sectional view taken along a line B-B′ shown in FIG. 5(a). The device indicates a silicon oxide film 111 grown by a thermal oxidization process, an interconnection pattern 112 formed on the silicon oxide film 104 grown by CVD, and a silicon oxide film grown by CVD. Like reference numerals used for describing the first embodiment denote like parts.

As is shown in FIG. 5(a), a plurality of pairs of slit-like gap regions (107a-107h) spaced from each other by a predetermined distance is provided on a side of the bonding pad 101 so as to surround window 108, and single slit-like gap regions (107i-107l) are provided in the window 108, each corresponding to one of the intermediate regions that are sandwiched by the associated pair of gap regions. That is, the gap regions (107a-107h) and the gap regions (107i-107l) are alternatively arranged in a zigzag formation. The zigzag arrangement functions to lengthen the effective length through which the gold atoms of the bonding wire are diffused when the bonding wire of gold is bonded to the bonding pad 101 and through which the aluminum molecules are diffused accordingly. Thus, the zigzag arrangement permits shortening the distance between the bonding pad 101 and the interconnection layer 102. This miniaturization and short-circuiting requirement between the bonding pad and the interconnection layer of the semiconductor device may be met.

The present layout assumes that interconnection layers (not shown) are provided to the upper, lower and right sides of the bonding pad 101, thus providing pairs of gap regions to all four outer edges of the bonding pad 101. In practice, the gap region may be provided at each side of the bonding pad to which the interconnection layer is provided. If only interconnection layer 102 is arranged proximate the bonding pad 101, only the paired gap regions 107a and 107b are employed and only the gap region 107i associated therewith is provided in window 108.

The above-mentioned layout may be realized using the following miniaturization process. A silicon oxide film 11 (having a thickness of approximately 300 nm) is grown on the main surface of a p-type semiconductor substrate 105 having a resistivity of approximately 20 Ω·m. Next, insulating film 104 of a silicon oxide film (having a thickness of approximately 700 nm) is grown on the silicon oxide film 111 using CVD. An interconnection pattern 112 is formed by growing AlCu copper (Cu: 0.5 wt %) to a thickness of approximately 500 nm by PVD and patterning it using standard photolithography techniques.

Silicon oxide film 113 is grown (having a thickness of approximately 900 nm) by CVD so as to cover interconnection pattern 112, and bonding pad 101 and interconnection layer 102 are formed on the silicon oxide film 113 again using standard photolithography techniques. Bonding pad 101 and interconnection layer 102 may be formed by growing an AlCu alloy (Cu: 0.5 wt %) to a thickness of approximately 500 nm by PVD and patterning the AlCu alloy film into the irrespective shapes. During patterning, gap regions 107a through 107l of the bonding pad 101 are formed. In the example shown in FIGS. 5A and 5B, each gap region is approximately 2 μm wide and approximately 20 μm length.

Subsequently, an SOG film (Spin On Glass: having a thickness of approximately 500 nm) and a silicon nitride film (having a thickness of approximately 700 nm) are grown in this order as passivation film 103. During SOG growth, the above-mentioned gap regions are filled with SOG. The passivation film 103 has a two-layer structure fills the gap regions with relatively soft SOG and effectively absorbs stress due to cubical expansion expected in later processes to thus prevent the occurrence of cracks. Passivation film 103 is then partially removed by etching, to form window 108 in bonding pad 101.

When window 108 is etched, gap regions 107a through 107h at the side of interconnection layer 102 are covered with passivation film 103. The SOG materials in gap regions 107a through 107h are not etched but remain therein. In contrast, gap regions 107i through 107l of the bonding pad 101 formed in the window 108 are not covered with the passivation film 103. Thus, the SOG materials in the gap regions 107i through 107l are removed by etching. Finally, the bonding wire (not shown) is bonded to bonding pad 101 through window 108.

Gap regions 107a through 107l function to absorb and distribute cubical expansion caused by heat applied during the sealing process (for example, 200° C., 5 hours) after connection with the bonding wire 106 is made and by ambient heat during use of the semiconductor device. Particularly, most cubical expansion is absorbed by gap regions 107i through 107l because these gap regions are “empty” (i.e., not full of SOG) and are close to the wire-bonding portion that is the source of substantial molecule movement. In addition, diffusion of the metal atoms from the region on the side of window 108 to the region on the side of interconnection layer 102 can be greatly suppressed, and the frequency of occurrence of cracks can be drastically reduced. It is thus possible to prevent the occurrence of cracks due to stress even when the interconnection pattern 112 is buried below the plane on which the bonding pad 101 and the interconnection layer 102 are provided.

The foregoing description is directed to the gap regions having a slit-like shape. However, the gap regions are not limited to the slit-like shape. The gap regions are required to function as a barrier that relaxes and distributes stress due to cubical expansion and prevents diffusion of metal atoms from the bonding pad into the interconnection layer. It is thus apparent that the shape, arrangement and number of gap regions can be modified depending on the positions of the gap regions.

As described above, according to the present invention, it is possible to provide a technique suitable for device miniaturization and capable of preventing short-circuiting in the bonding pad.

While at least one exemplary embodiment has been presented in the foregoing detailed description of the invention, it should be appreciated that a vast number of variations exist. It should also be appreciated that the exemplary embodiment or exemplary embodiments are only examples, and are not intended to limit the scope, applicability, or configuration of the invention in any way. Rather, the foregoing detailed description will provide those skilled in the art with a convenient road map for implementing an exemplary embodiment of the invention, it being understood that various changes may be made in the function and arrangement of elements described in an exemplary embodiment without departing from the scope of the invention as set forth in the appended claims and their legal equivalents.

1. A semiconductor device comprising:
a bonding pad; and
an interconnection line close to the bonding pad;
the bonding pad having a gap region that is provided in a region proximate to the interconnection line and runs in a direction substantially identical to a direction in which an edge of the bonding pad facing the interconnection line extends.

2. The semiconductor device as claimed in claim 1, wherein the bonding pad has at least three gap regions that are provided in the region proximate to the interconnection line and are arranged into lines.

3. The semiconductor device as claimed in claim 1, further comprising a single protection film that covers the interconnection line and a part of the bonding pad, wherein the gap region located in the part of the bonding part is filled with a part of the protection film.

4. The semiconductor device as claimed in claim 2, wherein the bonding pad has a window provided in an inner region thereof and used to bond a wire and at least one of the at least three gap regions is provided in the window.

5. The semiconductor device as claimed in claim 3, wherein the protection film is a multilayer film having a first relatively soft insulating film and a second relatively hard insulating film, and the part of the protection film provided in the gap region comprises a portion of the first insulating film.

6. The semiconductor device as claimed in claim 5, wherein the first insulating film is an SOG film, and the second insulating film is a silicon nitride film.

7. The semiconductor device as claimed in claim 1, further comprising sidewalls on sidewalls of the bonding pads that surround the gap region.

8. The semiconductor device as claimed in claim 7, wherein the sidewalls are made of titanium or an alloy containing titanium.

9. The semiconductor device as claimed in claim 1, further comprising a silicon oxide film that covers a buried interconnection pattern, wherein the bonding pad and the interconnection line are provided on the silicon oxide film.

10. A method of fabricating a semiconductor device comprising:
providing a conductive layer on an insulating layer; and
patterning the conductive layer into a bonding pad and an interconnection line close to the bonding pad so that that the bonding pad has a gap region that is provided in a region proximate to the interconnection line and runs in a direction substantially identical to a direction in which an edge of the bonding pad facing the interconnection line extends.

11. The method as claimed in claim 10, further comprising forming a window provided in an inner region of the bonding pad and used to bond a wire.

12. A method of fabricating a semiconductor device comprising:
forming a buried interconnection pattern covered by an insulating layer;
providing a conductive layer on the insulating layer; and
patterning the conductive layer into a bonding pad and an interconnection line close to the bonding pad so that that the bonding pad has a gap region that is provided in a region proximate to the interconnection line and runs in a direction substantially identical to a direction in which an edge of the bonding pad facing the interconnection line extends.
